(19) United States
(12) Patent Application Publication
(10) Pub. No.: US 2017/0064819 A1
(43) Pub. Date: Mar. 2, 2017

(54) PERFORATION ARRANGEMENT THROUGH WHICH INDIVIDUAL SUBSTRATES ARE TO BE DIVIDED FROM AGGREGATE SUBSTRATE AND AGGREGATE SUBSTRATE HAVING THE PERFORATION ARRANGEMENT

(71) Applicant: FANUC Corporation, Yamanashi (JP)

(72) Inventors: Hiroyuki SUWA, Yamanashi (JP); Yuuichi MATSUDA, Yamanashi (JP)

(21) Appl. No.: 15/246,585

(22) Filed: Aug. 25, 2016

(30) Foreign Application Priority Data
Aug. 27, 2015 (JP) 2015-168220

(51) Int. Cl. H05K 1/02

(52) U.S. Cl. CPC H05K 1/0271; H05K 2201/09063

(57) ABSTRACT

In a perforation arrangement having a number of small holes through which individual substrates of aggregate substrate are connected to each other where slits are provided between individual substrates in the aggregate substrate, the centers of the small holes are arranged so as not to be aligned in a straight line in a perforation. The small holes are arranged in or in proximity to a connection portion in such a manner that the distance of the center of each small hole from the line segment between the facing ends of the slits is different. The amount of stress concentrated on a perforation can be reduced, and therefore, the amount of stress applied to the parts mounted around the perforation can also be reduced in the case where the aggregate substrate are bent to be divided.

### BACKGROUND OF THE INVENTION

1. Field of the Invention

The present invention relates to a perforation arrangement through which individual substrates are to be divided from aggregate substrate and to aggregate substrate having the perforation arrangement.

2. Description of the Related Art

FIG. 1 is a diagram illustrating an example of aggregate substrate. Aggregate substrate 1 is formed of a number of individual substrates 2. In the conventional aggregate substrate 1, individual substrates 2 are connected through perforations 5 in connection portions 4 through which the individual substrates 2 are connected so that the individual substrates 2 can be divided when being bent. The perforation 5 is formed of a number of small holes 5a being aligned. Japanese Unexamined Patent Publication H7 (1995)-326828 discloses a perforation arrangement through which aggregate substrate in one sheet is divided into a number of individual substrates.

The aggregate substrate 1 can be divided into individual substrates 2 by bending it aggregate substrate along the perforations after parts have been mounted on the individual substrates 2. Therefore, stress is applied by the bending to the parts mounted around the perforation. Thus, it is important to reduce the stress applied to the periphery of the perforations 5 when being divided into individual substrates 2 in order to prevent a large amount of stress from being applied to the mounted parts.

A certain level of strength is required for the perforations 5 through which individual substrates 2 are connected in the aggregate substrate 1. The higher the strength is, the greater the amount of stress required is at the time of dividing through the perforations 5. FIG. 2 is a diagram showing the arrangement of a conventional perforation 5. FIG. 2 is a diagram showing an enlargement of a region 9 in FIG. 1. Slits 3 are provided between individual substrates 2 in the aggregate substrate 1. The perforation 5 formed of a number of small holes 5a is provided in or in proximity to the connection portions 4 between the slits 3 (portions defined between the ends 3a, 3a of the slits).

The centers of a number of small holes 5a are aligned in a straight line in a perforation 5 so that webs remained between the holes of the perforation 5 can be broken at the same time, and therefore, such a problem arises that the generated stress is high.

In Japanese Unexamined Patent Publication H7 (1995)-326828, auxiliary perforation is formed so as to be approximately parallel to the perforations. The auxiliary perforation is not intended to contribute to divide individual substrates from each other, but for preventing cracks created from a perforation from extending to a circuit pattern, and thus do not contribute to stress reduction when the individual substrates are divided from each other.

### SUMMARY OF THE INVENTION

In view of the above-described problem with the prior art, an object of the present invention is to provide a perforation arrangement along which individual substrates can be divided from aggregate substrate by bending the aggregate substrate with a smaller force, and to provide aggregate substrate having such a perforation arrangement.

The present invention provides a perforation arrangement formed of a number of small holes provided in connection portions for connecting individual substrates to each other in aggregate substrate, and in the perforation arrangement, the centers of the small holes are not aligned in a straight line. Thus, the perforation arrangement is characterized in that the centers of the small holes are arranged in an arc form or a V shape.

The present invention also provides aggregate substrate where a perforation formed of a number of small holes is provided in connection portions for connecting individual substrates to each other in aggregate substrate, and the aggregate substrate is characterized in that the centers in the perforations are not aligned in a straight line. Thus, the perforations are characterized in that the centers of the small holes are arranged in an arc form or a V shape.

The present invention can provide a perforation arrangement along which individual substrates can be divided from aggregate substrate by bending the aggregate substrate with a smaller force, and can provide aggregate substrate having such a perforation arrangement.

### BRIEF DESCRIPTION OF THE DRAWINGS

The above-described and other objects and features of the present invention will be clarified from the following descriptions of the embodiments in reference to the accompanying drawings, from among which:

FIG. 1 is a diagram showing an example of aggregate substrate;

FIG. 2 is a diagram showing a conventional perforation arrangement;

FIG. 3 is a diagram showing an embodiment of the present invention where holes are arranged in a perforation so as not to be aligned in a straight line;

FIG. 4 is a diagram showing another embodiment of the present invention where holes are arranged in an arc form in a perforation;

FIG. 5 is a diagram showing still another embodiment of the present invention where holes are arranged in a V shape in a perforation; and

FIG. 6 is a diagram showing the difference of the way of breaking between a conventional perforation arrangement and that of the present invention upon dividing the substrates along a perforation.

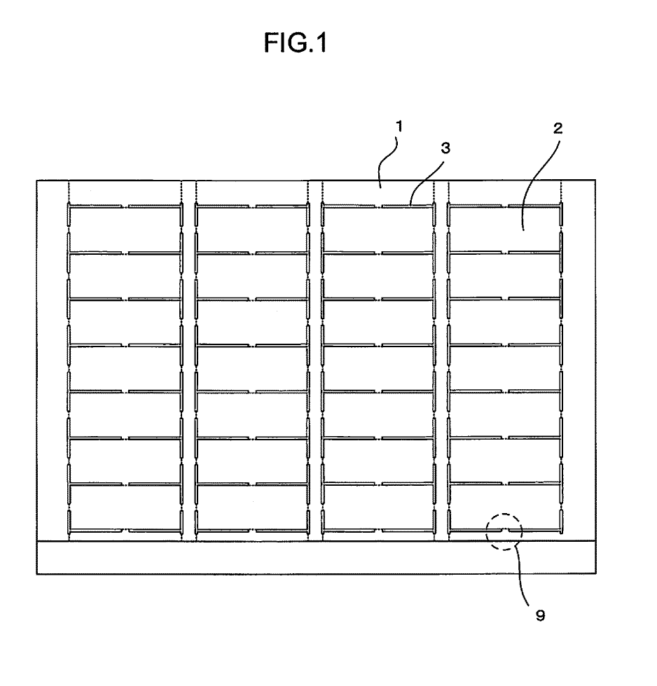

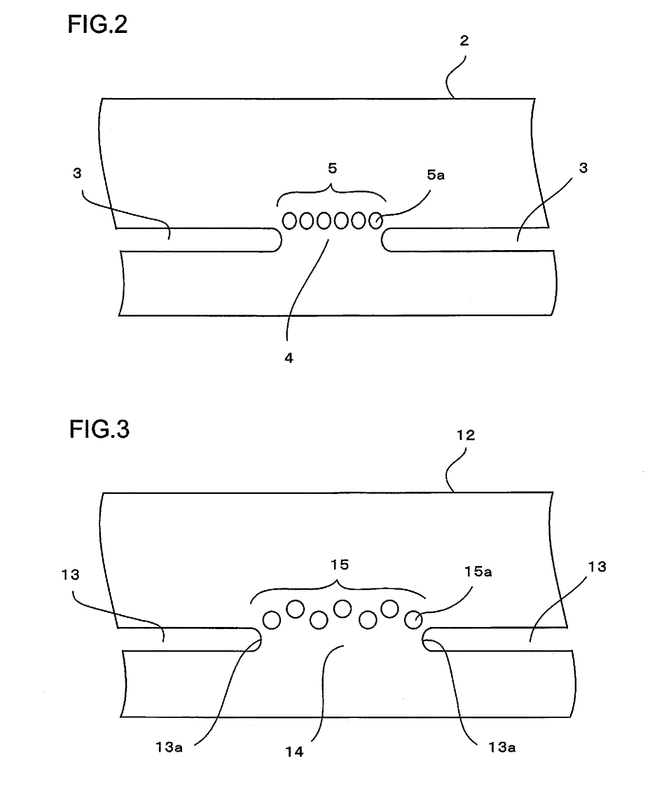

### DETAILED DESCRIPTION OF THE PREFERRED EMBODIMENTS

The preferred embodiments of the present invention will be described below with reference to the drawings. Here, the same symbols are attached to the components that are similar to those in the prior art for description. In aggregate substrate 1, a number of individual substrates are connected through connection portions in the same manner as in the prior art.

FIG. 3 is a diagram showing an embodiment of the present invention where holes are not aligned in a straight line in a perforation. Slits 13 are provided between individual substrates 12 in the aggregate substrate 1. A perforation 15 formed of a number of small holes 15a is provided in or in proximity to a connection portion 14 between slits 13. The perforation 15 has such a perforation arrangement that individual substrates 12 are connected to each other in the aggregate substrate 1 through a number of small holes 15a, so as not to align the centers of the small holes 15a in a straight line. The small holes 15a are arranged in or in proximity to the connection portion 14 in such a manner that the distance of the center of each small hole 15a from the line segment between the facing ends 13a of the slits is different. In FIG. 3, all the centers of the small holes 15a that form the perforation 15 are arranged on the same side relative to the line segment between the facing ends 13a of the slits. In the case where the aggregate substrate 1 is bent so as to be divided, the stress concentrated on the perforation is reduced, and therefore, the stress to be applied to the parts mounted around the perforation is also reduced.

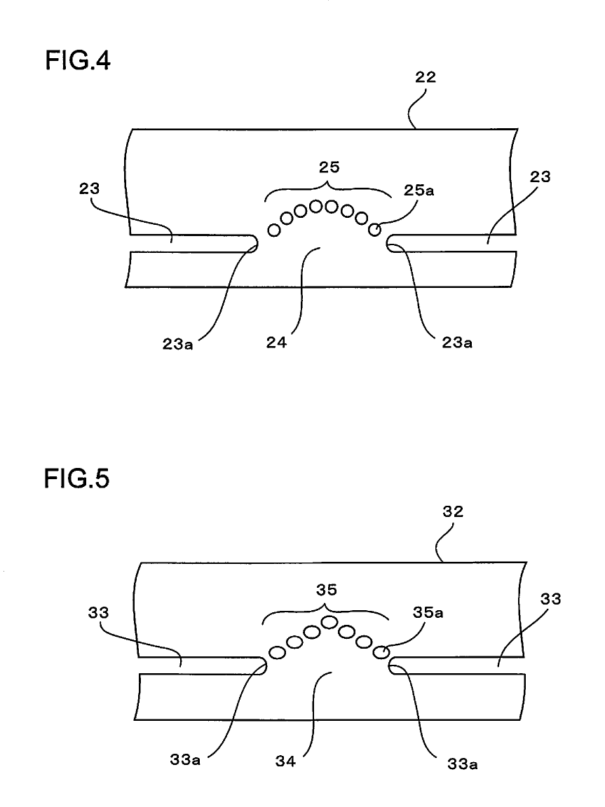

FIG. 4 is a diagram showing another embodiment of the present invention where holes are arranged in an arc form in a perforation. Slits 23 are provided between individual substrates 22 in aggregate substrate 1. A perforation 25 formed of a number of small holes 25a is provided in or in proximity to a connection portion 24 between the slits 23.

The small holes 25a are arranged in or in proximity to the connection portion 24 in such a manner that the distance of the center of each small hole 25a from the line segment between the facing ends 23a of the slits is different. The perforation 25 has such a perforation arrangement that the individual substrates 22 are connected to each other in the aggregate substrate 1 through the perforation, and the centers of the small holes 25a thereof are arranged in an arc form, and thus are arranged so as not to be aligned in a straight line connecting the ends of the slits.

FIG. 5 is a diagram showing still another embodiment of the present invention where the perforation is arranged in a V shape.

Slits 33 are provided between individual substrates 32 in aggregate substrate 1. A perforation 35 formed of a number of small holes 35a is provided in or in proximity to a connection portion 34 between slits 33.

The small holes 35a are arranged in or in proximity to the connection portion 34 in such a manner that the distance of the center of each small hole 35a from the line segment between the facing ends 33a of the slits is different. In the perforation 35, the centers of the small holes 35a are arranged in a V shape so as not to be aligned in a straight line.

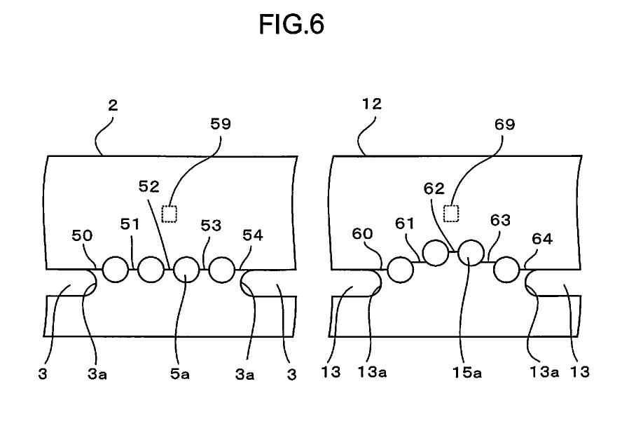

FIG. 6 is a diagram showing the difference of the way of breaking between a conventional perforation arrangement and that of the present invention upon dividing along a perforation. In FIG. 6, showing the arrangement of the conventional perforation (left half of the diagram) conventional perforation (left half of the diagram), portions 50, 51, 52, 53 and 54 between the respective small holes 5a crack when the substrates are to be divided. In contrast, showing the arrangement of the perforation (right half of the diagram) of the present invention where the holes are arranged in an arc form portions 60 and 64 first start cracking and are followed by portions 61 and 63 from among the portions between the respective small holes 15a, and therefore, the maximum stress is reduced. Thus, the connection webs (i.e. the webs remained between the small holes) in a perforation 25 or 35 crack one after another, which makes it possible to reduce the maximum stress when a number of small holes 25a are arranged in an arc form (FIG. 4) in a perforation 25, or a number of small holes 35a are arranged in a V shape (FIG. 5) in a perforation 35. A strain gauge was attached to the point 59 in the left half of the diagram and to the point 69 in the right half of the diagram in order to measure the amount of stress, where the points 59 and 69 were located at the same distance away from the center of the plane of an individual substrate 2 and an individual substrate 12, and such a result was achieved that the amount of stress was smaller in the perforation in the right half of the diagram than in the perforation in the left half of the diagram.

According to the present invention, the amount of stress concentrated on a perforation can be reduced, and therefore, the amount of stress applied to the parts mounted around the perforation can also be reduced in the case where aggregate substrate is bent to be divided. The perforation arrangement has such a form that holes are not aligned in a straight line, and thus, connection webs in a perforation can be prevented from breaking all at once when the substrate is bent to divide along the perforation. All the connection webs do not crack at the same time, and therefore, the amount of stress can be reduced.

The perforation arrangement according to the present invention is not limited to any of the embodiments in FIGS. 3 through 5 and includes any arrangement where the centers of a number of small holes are not aligned in a straight line as a whole as long as the effects of the present invention can be gained.

Though the preferred embodiments of the present invention are described in the above, the present invention is not limited to the above-described embodiments, and any appropriate modification can be applied or the invention can be implemented in other variations.

1. A perforation arrangement formed of a number of small holes provided in connection portions for connecting individual substrates in aggregate substrate, wherein the centers of the small holes are not aligned in a straight line.

2. The perforation arrangement according to claim 1, wherein the centers of the small holes are arranged in an arc form or in a V shape in the perforation.

3. Aggregate substrate comprising perforation formed of a number of small holes in connection portions for connecting individual substrates in the aggregate substrate, characterized in that the centers of the small holes are not aligned in a straight line as a whole in a perforation.

4. The aggregate substrate according to claim 3, characterized in that the centers of the small holes are arranged in an arc form or in a V shape in a perforation.
